(19) United States
(12) Patent Application Publication
(10) Pub. No.: US 2013/0126864 A1
(43) Pub. Date: May 23, 2013

(54) SEMICONDUCTOR JUNCTION ELEMENT, SEMICONDUCTOR DEVICE USING IT, AND MANUFACTURING METHOD OF SEMICONDUCTOR JUNCTION ELEMENT

(71) Applicants: Tadashi Fujieda, Mtio (JP); Takashi Naito, Funabashi (JP); Takuya Aoyagi, Hitachi (JP); Hiroki Yamamoto, Hitachi (JP); Motoyuki Miyata, Hitachinaka (JP)

(72) Inventors: Tadashi Fujieda, Mtio (JP); Takashi Naito, Funabashi (JP); Takuya Aoyagi, Hitachi (JP); Hiroki Yamamoto, Hitachi (JP); Motoyuki Miyata, Hitachinaka (JP)

(73) Assignee: HITACHI, LTD., Tokyo (JP)

(21) Appl. No.: 13/813,592

(22) PCT Filed: Sep. 2, 2011
(86) PCT No.: PCT/JP2011/070007

§ 371 Date: Jan. 31, 2013

(30) Foreign Application Priority Data
Sep. 24, 2010 (JP) 2010-213007

(51) Int. Cl. H01L 29/24; H01L 21/02

(52) U.S. Cl. CPC H01L 29/24; H01L 21/02565
USPC 257/43; 438/104

(57) ABSTRACT

In order to provide a semiconductor junction element consisted of an oxide semiconductor glass, which does not contain a toxic element and rare metal element, and various semiconductor devices using it, semiconductor glasses which contain vanadium oxide and have different polarities are connected each other in a semiconductor junction element of the present invention. Moreover, a semiconductor glass containing vanadium oxide is connected to an element semiconductor or a compound semiconductor which have different polarity from the semiconductor glass. Furthermore, a semiconductor glass containing vanadium oxide is connected to a metal.

### TECHNICAL FIELD

The present invention relates to a semiconductor junction element consisted of a semiconductor glass which contains vanadium oxide, a solar battery cell, a thermoelectric element, various diodes, and various transistors using it.

### BACKGROUND ART

As a semiconductor glass, a non-oxide chalcogenide glass is known in which a chalcogen element such as S, Se, and Te is used by itself or in combination with other elements. The followings are well-known as a p-n junction using a chalcogenide glass. Nonpatent literature 1 discloses a p-n junction wherein p-type semiconductor of As2Se3 or Ge20Se80 thin film is deposited over an n-type Ge20Bi11Se69 bulk glass.

In addition, nonpatent literature 2 discloses a p-n junction consisted of all chalcogenide glass thin films.

On the other hand, there is little example of studying a p-n junction which uses an oxide glass.

In chalcogen elements, Te is a toxic element, Ge adding as a chalcogen glass component is a rare metal element, and As is a toxic element.

### CITATION LIST

### Nonpatent Literature

### Non-Patent Literature 1:

N. Tohge, K. Kanda and T. Minami, Appl. Phys. Lett., 48, 1739 (1986)

### Non-Patent Literature 2:

N. Tohge, K. Kanda and T. Minami, Appl. Phys. Lett., 53, 580 (1988)

### SUMMARY OF INVENTION

### Technical Problem

The object of the present invention is providing a semiconductor junction element consisted of an oxide semiconductor glass which does not use a toxic element and a rare metal element, and providing various devices using it.

### Solution to Problem

The present invention is characterized by jointing semiconductor glasses each other which contain vanadium oxide and have different polarities. Moreover, it is characterized in that at least a part of the aforementioned semiconductor glass is crystallized.

### Advantageous Effect of Invention

According to the present invention, because the semiconductor glass containing vanadium oxide has a low melting point, it is easily formed to a thin film and a complex shape. Additionally, because it has excellent processability, a semiconductor junction element with various shapes can be manufactured.

### BRIEF DESCRIPTION OF DRAWINGS

FIG. 1 is a cross-sectional schematic drawing illustrating a solar battery cell according to the third embodiment.

FIG. 2 is a structural drawing of a pair of cascade-form thermoelectric element according to the fourth embodiment.

### DESCRIPTION OF EMBODIMENTS

Hereafter, the present invention will be described in detail.

A semiconductor glass consisted of vanadium oxide does not contain a toxic element and a rare metal element, and the semiconductor polarization can be controlled by the valence control of vanadium ion. Concretely, it becomes p-type semiconductor when tetravalent vanadium ion is relatively increased, and it becomes n-type semiconductor when pentavalent vanadium ion is relatively increased.

A semiconductor junction element of the present invention is one that semiconductor glasses which contain vanadium oxide and have different polarities are jointed each other. Moreover, a semiconductor glass containing vanadium oxide is jointed with an element semiconductor or a compound semiconductor which has different polarity from the semiconductor glass. Furthermore, a semiconductor glass containing vanadium oxide is jointed with a metal.

A manufacturing method of a junction element of the semiconductor glasses is characterized by oxidizing or reducing the surface of the semiconductor glass. On the other hand, it is characterized in that the junction element of the semiconductor glass with an element semiconductor, a compound semiconductor, or a metallic material is manufactured by anode jointing. As a result, cost-reduction by simplifying the manufacturing process is further possible.

A semiconductor junction element of the present invention can be applied to a solar battery cell, a thermoelectric element, various diodes, and various transistors.

Hereafter, embodiments of the present invention will be described.

### First Embodiment

### Manufacturing a Junction Element of Semiconductor Glasses 1

200 g of mixed powder in which Sb₂O₃, V₂O₅, P₂O₅, and Fe₂O₃ were blended and mixed to be 28%, 50%, 12%, and 10% in weight ratio respectively was put in a platinum crucible, and it was heated up to 1100° C. with a heating-rate of 5 to 10° C./min (° C./minute) using an electric furnace and kept it for two hours. It was stirred to obtain homogeneous glass while maintaining. Next, the platinum crucible was taken out from the electric furnace and poured it over a stainless plate heated to 150-200° C. beforehand. The coagulum had glassy luster.

The ratio of tetravalent vanadium ion (V⁴⁺) and pentavalent vanadium ion (V⁵⁺) in the glass were measured by an oxidation-reduction titration method and obtained the result of V⁴⁺/V⁵⁺<1. As a result, it was confirmed that this glass was a p-type semiconductor.

This glass was processed to be the size of about 10×10×3 mm³ and used as a test piece.

Next, only the surface thereof was oxidized by irradiating microwave (single mode method) to the glass surface in atmosphere. Concretely, microwave of 2.45 GHz was introduced from the magnetron oscillator into the wave guide wherein one side was plugged by a reflector, the microwave was propagated in TE10 mode in the wave guide, and the single-mode microwave radiation was carried out to the test piece put in the wave guide. The microwave could be irradiated from two systems to enable the independent control of the electric field and the magnetic field in a specific sample position. That is, the power ratio of the electric field and the magnetic field at the sample position has been changed by making a strong electric field at the sample position by irradiation of the first system, making a strong magnetic field at the same position by irradiation of the second system, and controlling the outputs of these two systems individually. The microwave radiation mode may be a multimode method and it is not specifically limited.

The electrodes were formed over the both sides of the glass after the microwave radiation face was made flat by polishing, a voltage started applying to the both sides so as to apply a negative voltage to the polished face, and thereby current began to flow rapidly. On the contrary, current did not flow even if a voltage was applied to the both sides so as to apply a positive voltage to the polished face, and rectification was observed. From this fact, it is considered that the surface of the p-type crystallized glass was oxidized by microwave radiation and n-type layer was formed.

### Second Embodiment

### Manufacturing a Junction Element of Semiconductor Glasses 2

200 g of mixed powder in which Cu₂O, V₂O₅, Fe₂O₃, and P₂O₅ were blended and mixed to be 10%, 70%, 10%, and 10% in molar fraction respectively was put in a platinum crucible, and it is heated up to 1100° C. with a heating-rate of 5 to 10° C./min (° C./minute) using an electric furnace and kept it for two hours. It was stirred to obtain homogeneous glass while maintaining. Next, the platinum crucible was taken out from the electric furnace and poured it over a stainless plate heated to 150-200° C. beforehand. The coagulum had glassy luster.

After the microwave radiation face was made flat by polishing, this glass was processed to be the size of about 10×10×3 mm³ and used as a test piece, and it was crystallized by heat-treatment at 480° C. for 8 hours by using an electric furnace. The Seebeck coefficient of this glass was a negative value, and it was an n-type semiconductor.

Next, only surface was reduced by irradiating microwave (single mode method) to the crystallized glass surface in reducing atmosphere such as hydrogen atmosphere and water vapor atmosphere, etc. The microwave radiation method is similar to the above-mentioned first embodiment. In this embodiment, the microwave radiation mode may be a multimode method and is not specifically limited.

The electrodes were formed over the both sides of the glass, a voltage started applying to the both sides so as to apply a positive voltage to the polished face, and thereby current began to flow rapidly. On the contrary, current did not flow even if a voltage was applied to the both sides so as to apply a negative voltage to the polished face, and rectification was observed. From this fact, it is considered that the surface of the n-type crystallized glass was reduced by microwave radiation and p-type layer was formed.

### Third Embodiment

### Manufacturing a Junction Element of a Semiconductor Glass with an Elemental Semiconductor or a Compound Semiconductor

200 g of mixed powder in which K₂CO₃, V₂O₅, Fe₂O₃, and P₂O₅ were blended and mixed to be 10%, 70%, 10%, and 10% in molar fraction respectively was put in a platinum crucible, and it is heated up to 1100° C. with a heating-rate of 5 to 10° C./min (° C./minute) using an electric furnace and kept it for two hours. It is stirred to obtain homogeneous glass while maintaining heating. Next, the platinum crucible was taken out from the electric furnace and poured it over a stainless plate heated to 200-300° C. beforehand. The coagulum has glassy luster.

This glass was processed to be the size of about 10×10×0.5 mm³, one side was processed by mirror polishing, and an electrode was formed over another side. In addition, a p-type Si wafer was prepared wherein an electrode was formed over one side. In the state of connecting the glass with the p-type Si wafer, wherein this mirror surface of the glass was directly contacted by using a clump to the p-type Si wafer face on which an electrode was not formed, a negative electric field (10⁵ to 10⁶ V/m) was applied to the glass surface which is not connected to the p-type Si wafer face and heated them at 400° C. in atmosphere. In this case, current flowing between the p-type Si wafer surface and the glass surface was monitored, and the current application and heating were assumed to be end when the current decreased up to 5% of the maximum current. This bonding method is called an Anodic Bonding.

A voltage was applied to the both sides so as to apply a positive voltage to the Si surface and, thereby, current began to flow rapidly as well as the first embodiment. On the contrary, current did not flow even if a voltage was applied to the both sides so as to apply a negative voltage to the Si surface, and rectification was observed. From this fact, it is considered that the glass becomes n-type and a p-n junction was formed.

Instead of the Si wafer, this anodic bonding method can be applied to the junction between a semiconductor glass containing vanadium oxide and a compound semiconductor or a metal. And it also can be also applied to the junction between a semiconductor glass containing an alkaline metal and vanadium oxide and a semiconductor glass which does not contain an alkaline metal and contains vanadium oxide.

### Fourth Embodiment

### Manufacturing a Junction Device by a Coating Process

Because a semiconductor glass containing vanadium oxide in the present invention has a low softing point and enable to be fired at a low temperature, deposition by using an easy thick-film formation process can be applied such as a screen printing method, an ink jet method, a stump method, and a photoresist film method, etc. Therefore, over a mirror polished face of a semiconductor glass, an element semiconductor, and a compound semiconductor, a paste consisted of a semiconductor glass powder having the opposite polarity to these semiconductors, an organic binder, and an organic solvent is coated by using the above-mentioned thick-film formation process; deliquoring is carried out by heating; and then it is fired by holding the temperature at the softing point of the glass or more, resulting in obtaining the semiconductor junction element. Then, it is also possible to crystallize the semiconductor glass by further heating at the crystallization temperature. When the degree of sintering of the semiconductor glass is not good, a vanadium oxide glass having a lower melting point than the used semiconductor glass may be added. Moreover, a Schottky junction element can be easily manufactured by forming a semiconductor film over a mirror polished face of the metal by using the similar method described above.

### Fifth Embodiment

### Solar Battery Cell

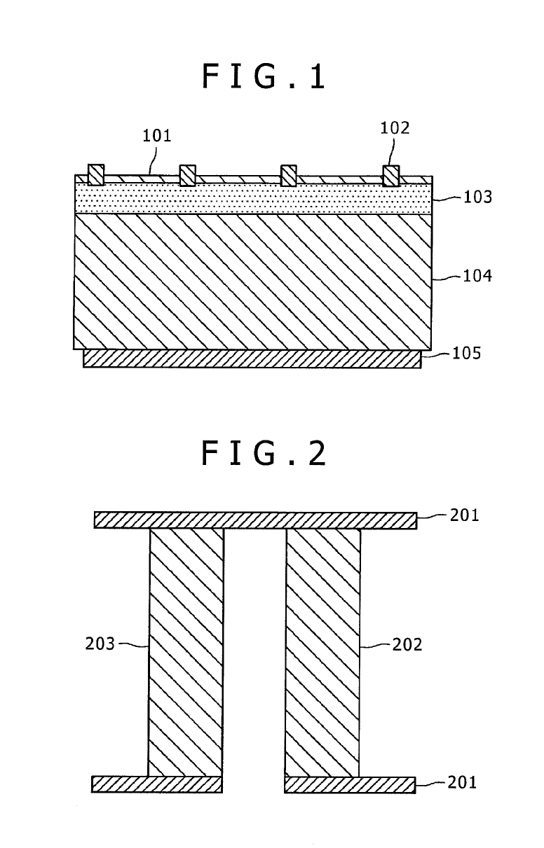

FIG. 1 is a cross-sectional drawing of a solar battery cell using a p-n semiconductor junction element wherein n-type semiconductor crystallized glass 103 containing vanadium oxide is jointed to a p-type crystal Si substrate 104 by using any method described above. Moreover, instead of the p-type crystal Si substrate 104, a p-type semiconductor crystallized glass substrate may be used. An antireflection film 101 and a surface electrode 102 are formed over the surface of the n-type semiconductor, and back-electrode 105 is formed over the rear face of the p-type semiconductor.

The p-n junction element of the present invention is not limited to the solar battery cell having the structure shown in FIG. 1, but it can be applied to back-electrode type (back-contact type) solar battery cell, etc. which does not have an electrode over the light receiving face.

### Sixth Embodiment

### Thermoelectric Power Generation Module

FIG. 2 is a structural drawing of a π shape thermoelectric element which is formed by making a Schottky junction of n-type semiconductor crystallized glass 202 and a p-type semiconductor crystallized glass 203 with the metal electrode 201 by using any method described above. A thermoelectric power generation module can be manufactured by electrically connecting the elements in parallel or series respectively.

### LIST OF REFERENCE SIGNS

101 Antireflection film
102 Surface electrode
103, 202 n-type semiconductor crystallized glass
104 p-type Si substrate
105 back-electrode
201 metal electrode
203 p-type semiconductor crystallized glass

1. A semiconductor junction element, wherein semiconducting glasses containing vanadium oxide and having different polarities are connected each other.

2. The semiconductor junction element according to claim 1, wherein at least a part of said semiconductor glass are crystallized.

3. The semiconductor junction element according to claim 2, wherein semiconductor glasses having different crystallization rates are connected each other.

4. A semiconductor junction element, wherein a semiconductor glass containing vanadium oxide is connected to an element semiconductor or a compound semiconductor having different polarity from said semiconductor glass.

5. A Schottky junction element, wherein a semiconductor glass containing vanadium oxide is connected to a metal.

6. A manufacturing method of semiconductor junction element, wherein a surface of semiconductor glass is oxidized or reduced.

7. A manufacturing method of a semiconductor junction element, wherein a semiconductor glass containing vanadium oxide is connected to an element semiconductor and a compound semiconductor or a metal by using an anode-bonding.

8. A solar battery cell, wherein a semiconductor junction element described in claim 1 is used.

9. A thermoelectric element, wherein a semiconductor junction element described in claim 1 is used.

10. A diode, wherein a semiconductor junction element described in claim 1 is used.

11. A transistor, wherein a semiconductor junction element described in claim 1 is used.
